(19) United States
(12) Patent Application Publication
(10) Pub. No.: US 2011/0012240 A1
(43) Pub. Date: Jan. 20, 2011

(54) Multi-Connect Lead

(76) Inventors: Chenglin Liu, San Jose, CA (US); Thomas Ngo, San Jose, CA (US); Xiaoting Chang, Milpitas, CA (US)

Correspondence Address: Sadler, Breen, Morasch & Colby, ps, 601 W. Main Ave., Suite 1300, Spokane, WA, 99201, US

(21) Appl. No.: 12/830,802

(22) Filed: Jul. 6, 2010

Related U.S. Application Data
(60) Provisional application No. 61/225,765, filed on Jul. 15, 2009.

(51) Int. Cl. H01L 23/495; H01L 21/60

(52) U.S. Cl. 257/666; 438/123; 257/E23.031; 257/E21.506

(57) ABSTRACT

This disclosure describes a multi-connect lead providing multiple connections using one external pin. In one embodiment, a lead frame for a lead-frame-based chip package includes a multi-connect lead that uses one external pin and enables multiple electrical connections to an integrated circuit die.

### RELATED APPLICATION

This application claims priority to U.S. Provisional Patent Application Ser. No. 61/225,765 filed Jul. 15, 2009, the disclosure of which is incorporated by reference herein in its entirety.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

Conventional lead-frame-based chip packages include multiple external pins. Each external pin is connected to a lead. Within the chip package, each lead is connected to an integrated circuit die via a wire. In this way internal circuitry within the integrated circuit die is electrically connected, through the external pins, to a printed circuit board on which the chip package is mounted. Many conventional chip packages use multiple external pins to provide multiple power and ground connections to an integrated circuit die. This reduces the pin count available for input/output and/or requires an expensive upgrade to a lead-frame with higher pin-count.

### SUMMARY

This summary is provided to introduce subject matter that is further described below in the Detailed Description and Drawings. Accordingly, this Summary should not be considered to describe essential features nor used to limit the scope of the claimed subject matter.

In one embodiment, an apparatus is described that comprises an external pin configured to establish an electrical connection to an external apparatus, a multi-connect lead comprising: a pin-connect section directly connected to the external pin; a die-connect section directly connected to the pin-connect section and configured to allow multiple electrical connections to an integrated circuit die; and a support section directly connected to the die-connect section, providing support to the die-connect section, and having an end, the end electrically and physically terminating the multi-connect lead, and a lead supporter in contact with the pin-connect section and the support section but not in contact with the die-connect section, the lead supporter providing mechanical support to the support section and the pin-connect section.

In another embodiment a chip package is described that comprises an integrated circuit die; an external pin mounted to the chip package and configured to establish an electrical connection to an external apparatus; a multi-connect lead mounted to the chip package and comprising: a pin-connect section directly connected to the external pin; and a die-connect section, the die-connect section directly connected to the pin-connect section, configured to allow multiple electrical connections to the integrated circuit die, and having an end, the end electrically and physically terminating the multi-connect lead, and a lead supporter in contact with the pin-connect section but not in contact with the die-connect section, the lead supporter providing mechanical support to the pin-connect section.

In yet another embodiment a method is described that comprises attaching a multi-connect lead to a lead-frame substructure, the multi-connect lead comprising: a pin-connect section directly connected to an external pin, the external pin residing on an outside edge of the lead-frame substructure; a die-connect section directly connected to the pin-connect section and configured to allow multiple electrical connections to an integrated circuit die; and a support section directly connected to the die-connect section, providing support to the die-connect section, and having an end, the end electrically and physically terminating the multi-connect lead, and attaching a lead supporter to the pin-connect section and the support section but not to the die-connect section.

### BRIEF DESCRIPTION OF THE DRAWINGS

The detailed description is described with reference to the accompanying figures. In the figures, the left-most digit of a reference number identifies the figure in which the reference number first appears. The use of the same reference numbers in different instances in the description and the figures indicate similar or identical items.

FIG. 1 illustrates a top-down view of a chip package having a multi-connect lead.

FIG. 2 illustrates top-down views of a multi-connect lead with one support section.

FIG. 3 illustrates top-down views of a multi-connect lead with two support sections.

FIG. 4 illustrates top-down views of a multi-connect lead having no support sections.

FIG. 5 illustrates a top-down view and a cross-section view of a portion of a chip package having a multi-connect lead.

FIG. 6 illustrates a different cross-section view of the chip package illustrated in FIG. 5.

FIG. 7 illustrates another cross-section view of the chip package illustrated in FIGS. 5 and 6.

FIG. 8 illustrates a cross-section view of a similar chip package to the chip package illustrated in FIGS. 5, 6, and 7, the similar chip package having different levels of elevation for leads.

FIG. 9 illustrates a method for conserving external pins for I/O use and/or space occupied by leads on a chip package.

### DETAILED DESCRIPTION

As noted in the Background above, conventional lead-frame-based chip packages use multiple pins for power and multiple pins for ground, resulting in fewer pins being available for input/output (I/O) and/or higher costs.

Operating Environment

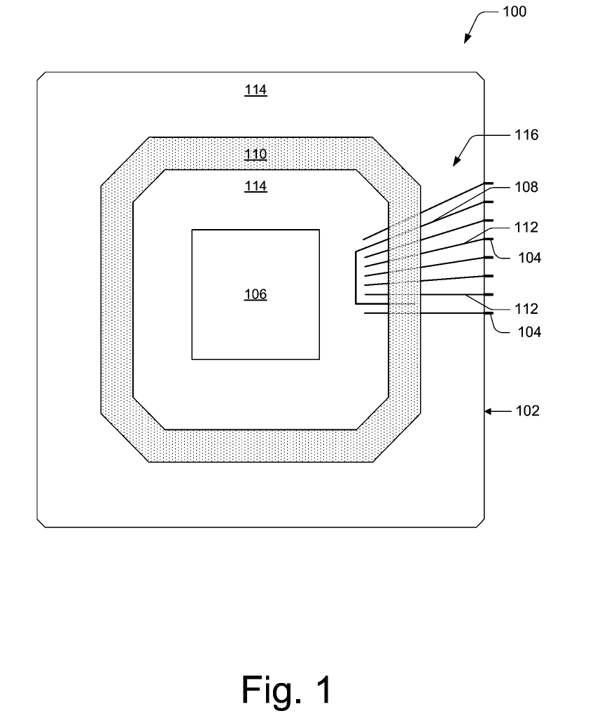

FIG. 1 illustrates a lead-frame-based chip package 100, having an external edge 102 with external pins 104, an integrated circuit die 106, a multi-connect lead 108, a lead supporter 110, single-connect leads 112, and lead-frame substructure 114. External edge 102, external pins 104, multi-connect lead 108, single-connect leads 112, and lead-frame substructure 114 together make up lead frame 116.

For clarity, one external edge 102 is illustrated with external pins 104, though external pins 104 can be located on multiple edges of chip package 100 (e.g., a 128-pin lead-frame-based chip package having thirty-two external pins 104 on each of four edges). External pins 104 serve as electrical connections to a printed circuit board (not shown) on which chip package 100 is, or will be, mounted. Integrated circuit die 106 includes internal circuitry, which, when properly connected to the printed circuit board (not shown), serves as part of a functional circuit. For example, integrated circuit die 106 may serve as a memory chip of RAM, a central processing unit, or an audio or Ethernet controller.

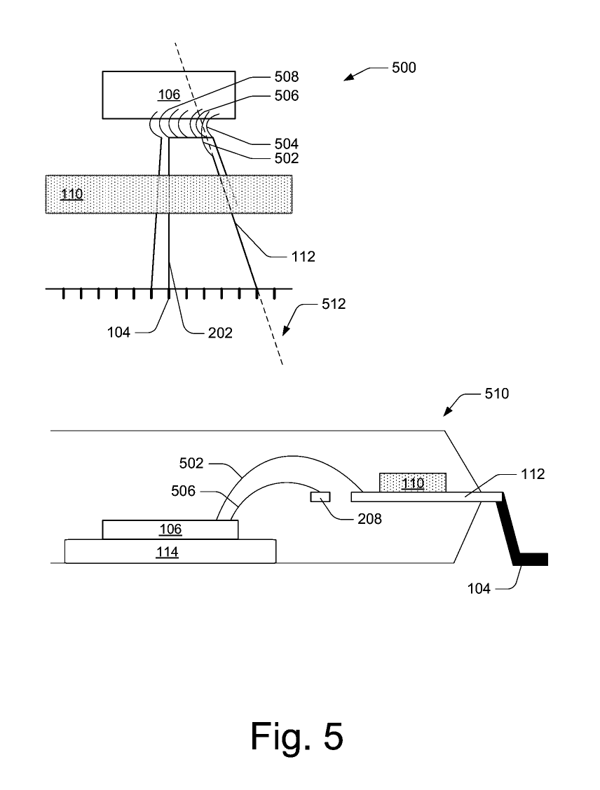

Multi-connect lead 108 enables multiple electrical connections to integrated circuit die 106 using only one external pin 104. For example, if this one external pin 104 is attached to a power source on the printed circuit board, multi-connect lead 108 provides multiple wire connections to power integrated circuit die 106. For clarity, bonding wires are not shown in FIG. 1, but are illustrated in FIGS. 5-8.

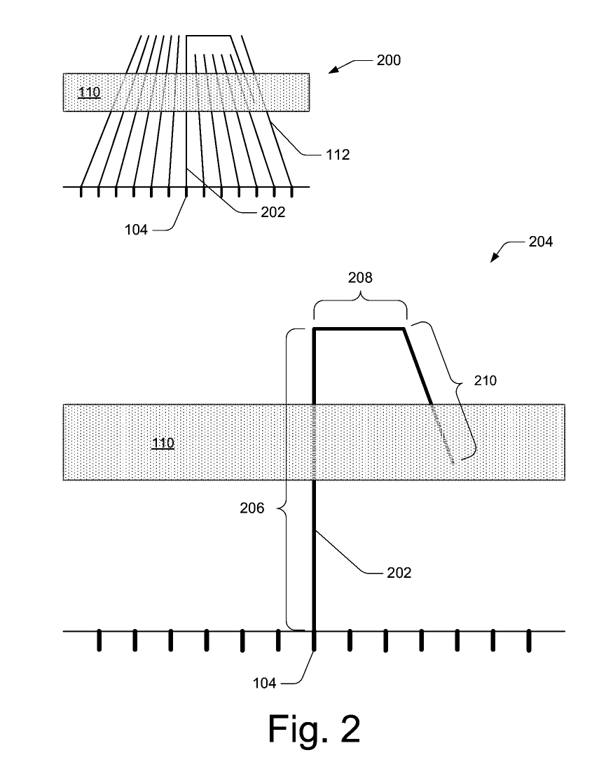

View 200 of FIG. 2 illustrates a multi-connect lead 202 with a similar shape to that of multi-connect lead 108 of FIG. 1. Multi-connect lead 202 is connected to an external pin 104 and is configured to allow multiple connections to integrated circuit die 106 (not shown in FIG. 2). Multiple single-connect leads 112 are shown in close proximity to multi-connect lead 202. A portion of lead supporter 110 is shown, which resides over portions of leads 112 and 202.

Expanded view 204 is an expanded view of a portion of view 200; single-connect leads 112 have been removed for clarity. Multi-connect lead 202 includes three sections: a pin-connect section 206; a die-connect section 208; and a support section 210. Pin-connect section 206 connects to one of external pins 104 at a first end and is in physical (but not electrical) contact with lead supporter 110. Pin-connect section 206 connects to die-connect section 208 at a second end. Die-connect section 208 is connected to pin-connect section 206 at a first end and is configured to have multiple bonding wires attached, allowing multiple electrical connections to integrated circuit die 106. Die-connect section 208 is not in contact with lead supporter 110 but connects to support section 210 at a second end. Support section 210 is connected to die-connect section 208 at a first end and is in physical contact with lead supporter 110. A second end of support section 210 is not in contact with any other section or an external pin 104. This second end of support section 210 electrically and physically terminates multi-connect lead 202.

Various angles between sections of multi-connect lead 202 are shown, though many other angles are contemplated. As shown, pin-connect section 206 is parallel to external pin 104, pin-connect section 206 and die-connect section 208 intersect at a ninety degree angle, and die-connect section 208 and support section 210 intersect at an angle greater than ninety degrees.

Support section 210 extends only part of the way under lead supporter 110, but lengths extending beyond lead supporter 110 are contemplated. Furthermore, support section 210 may reverse direction and come back out from under lead supporter 110 at the side of lead supporter 110 closest to integrated circuit die 106.

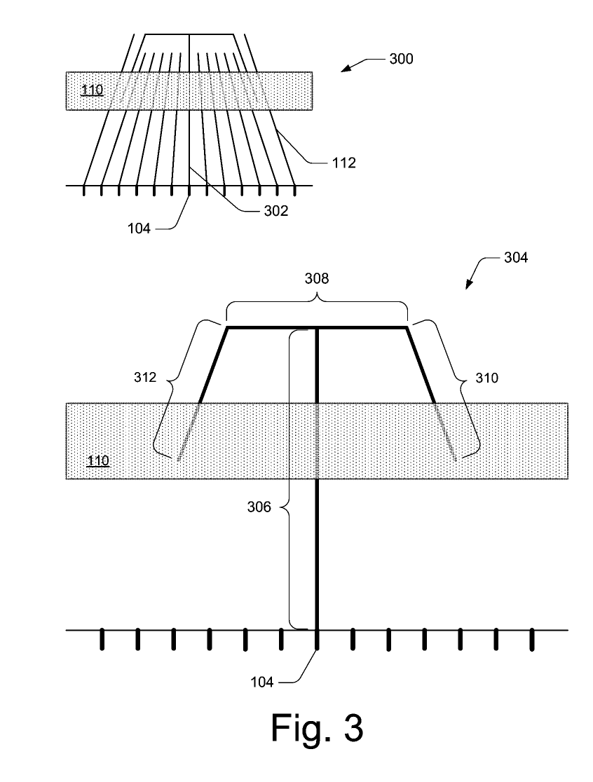

View 300 of FIG. 3 illustrates a multi-connect lead 302 with an additional support section compared to that of multi-connect lead 202 of FIG. 2. Multi-connect lead 302 connects to external pin 104 and allows multiple connections to integrated circuit die 106 (not shown in FIG. 3). A portion of lead supporter 110 is shown and resides over portions of leads 112 and 302.

Expanded view 304 is an expanded view of a portion of view 300; single-connect leads 112 have been removed for clarity. Multi-connect lead 302 includes four sections: a pin-connect section 306, a die-connect section 308, a first support section 310, and a second support section 312. Pin-connect section 306 connects to one of external pins 104 at a first end and is in physical (but not electrical) contact with lead supporter 110. Pin-connect section 306 connects to die-connect section 308 at a second end. Die-connect section 308 is connected to pin-connect section 306 and is configured to have multiple bonding wires attached, allowing multiple electrical connections to integrated circuit die 106. Die-connect section 308 is not in contact with lead supporter 110 but connects to first support section 310 at a first end. First support section 310 is connected to die-connect section 308 at a first end and is in physical contact with lead supporter 110. A second end of first support section 310 is not in contact with any other section or an external pin 104. This second end of first support section 310 electrically and physically terminates multi-connect lead 302. Die-connect section 308 is connected to second support section 312 at a second end. Second support section 312 is connected to die-connect section 308 at a first end and is in physical contact with lead supporter 110. A second end of second support section 312 is not in contact with any other section or an external pin 104. This second end of second support section 312 also electrically and physically terminates multi-connect lead 302.

Various angles between sections of multi-connect lead 302 are shown, though many other angles are contemplated. As shown, pin-connect section 306 is parallel to external pin 104, pin-connect section 306 and die-connect section 308 intersect at a ninety degree angle, and die-connect section 308 intersects with support sections 310 and 312 at angles greater than ninety degrees.

Support sections 310 and 312 extend only part of the way under lead supporter 110, but lengths extending beyond lead supporter 110 are contemplated. Furthermore, support sections 310 and 312 may reverse direction and come back out from under lead supporter 110 at the side of lead supporter 110 closest to integrated circuit die 106.

These multi-connect leads (108, 202, and 302) and single-connect leads 112 receive mechanical support through their connection to an external pin 104. Because of their geometry, multi-connect leads 108, 202, and 302 are more fragile than single-connect leads 112. Without lead supporter 110, multi-connect leads 108, 202, and 302 may be damaged while wire bonding to integrated circuit die 106 or during application of a structural material that is used in most conventional chip packages. As shown in FIGS. 2 and 3, die-connect sections 208 and 308 are fragile. To mitigate this fragility, support sections 210, 310, and 312 are in contact with lead supporter 110. Each support section on a multi-connect lead provides additional support, which allows for a larger die-connect section and thus more electrical contacts to integrated circuit die 106.

In this embodiment, lead supporter 110 is an electrically insulating plastic. Lead supporter 110 serves as a mechanical support for the multi-connect leads (108, 202, and 302) within chip package 100. The collection of leads in chip package 100 is commonly known as a lead frame (116) as it forms a “frame” around the integrated circuit die. In FIG. 1, lead frame 116 includes external edge 102, external pins 104, multi-connect lead 108, single-connect leads 112, and lead-frame substructure 114. Lead supporter 110 may provide additional mechanical support for the entire lead frame because it is also attached to single-connect leads 112 as shown in FIG. 1. This additional support may reduce multi-connect and/or single-connect lead failures during chip manufacture.

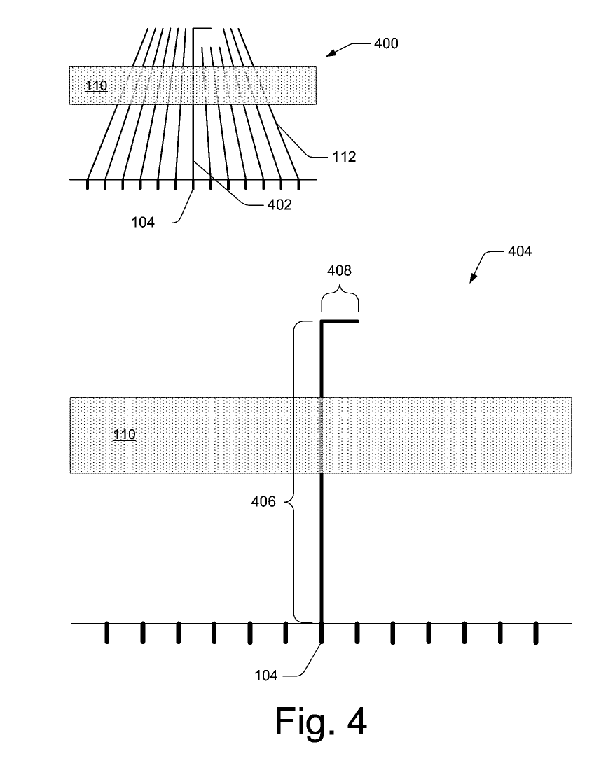

View 400 of FIG. 4 illustrates a multi-connect lead 402 that does not include a support section. Multi-connect lead 402 is connected to external pin 104 and is configured to allow multiple connections to integrated circuit die 106 (not shown in FIG. 4). A portion of lead supporter 110 is shown and resides over portions of leads 112 and 402.

Expanded view 404 is an expanded view of a portion of view 400; single-connect leads 112 have been removed for clarity. Multi-connect lead 402 includes two sections: a pin-connect section 406 and a die-connect section 408. Pin-connect section 406 connects to one of external pins 104 at a first end and is in physical (but not electrical) contact with lead supporter 110. Pin-connect section 406 connects to die-connect section 408 at a second end. Die-connect section 408 is connected to pin-connect section 406 at a first end and is configured to have multiple bonding wires attached, allowing multiple electrical connections to integrated circuit die 106. Die-connect section 408 is not in contact with lead supporter 110. A second end of die-connect section 408 is not in contact with any other section or an external pin 104. This second end of die-connect section 408 electrically and physically terminates multi-connect lead 402.

As shown, pin-connect section 406 is parallel to external pin 104 and intersects die-connect section 408 at a ninety-degree angle, though other angles are contemplated.

Lead supporter 110 is shown in FIG. 4 though multi-connect lead 402 does not utilize it via a support section. Instead, die-connect section 408 is kept short enough to be mechanically sound while still providing multiple connections to integrated circuit die 106 via bonding wires.

Though multi-connect leads 202, 302, and 402 are described as including sections it is contemplated that multi-connect leads 108, 202, 302, and 402 may be comprised of one continuous material described as sections according to function or may be comprised of separate sections of material, which are joined together to form the lead. Although the sections of multi-connect leads 108, 202, 302, and 402 are shown as being straight lines, other forms are contemplated. For example, each section may include one or more curved lines or may include multiple lines that are not parallel with each other.

Referring back to FIG. 1, single-connect leads 112 are conventional leads in that they connect to one external pin 104 and are configured to allow one wire bonding (wire-based electrical connection) to integrated circuit die 106. As shown in FIG. 1, several single-connect leads 112 are located behind part of the multi-connect lead 108 in relation to integrated circuit die 106. These single-connect leads 112 may still be connected to integrated circuit die 106 via wires that are not in contact with multi-connect lead 108.

Lead-frame substructure 114 is a structural material that is electrically insulating and acts as a base for other components. For example, leads 108 and 112 and integrated circuit die 106 rest on top of lead-frame substructure 114.

View 500 of FIG. 5 is similar to view 200 FIG. 2 except that a portion of integrated circuit die 106 is shown, all but two of single-connect leads 112 have been removed, and wires 502, 504, 506, and 508 are shown (among other unlabeled wires). Wire 502 electrically connects single-connect lead 112 to integrated circuit die 106. Wires 504, 506, and 508 electrically connect multi-connect lead 202 to integrated circuit die 106.

View 510 is a cross-section indicated by dashed line 512 of view 500. A portion of lead-frame substructure 114 is shown for context. Die-connect section 208 of multi-connect lead 202 is shown in front of single-connect lead 112 in relation to integrated circuit die 106. Die-connect section 208 and single-connect lead 112 are electrically insulated from each other. Wire 506 electrically connects die-connect section 208 to integrated circuit die 106 without interfering with wire 502's connection. Wire 502 electrically connects single-connect lead 112 to integrated circuit die 106 without interfering with wire 506's connection. In this embodiment, lead supporter 110 is in contact with single-connect lead 112 but not with die-connect section 208. External pin 104 is shown angling down and then out but other shapes are contemplated, such as an external pin that is parallel to and on the same level as single-connect lead 112.

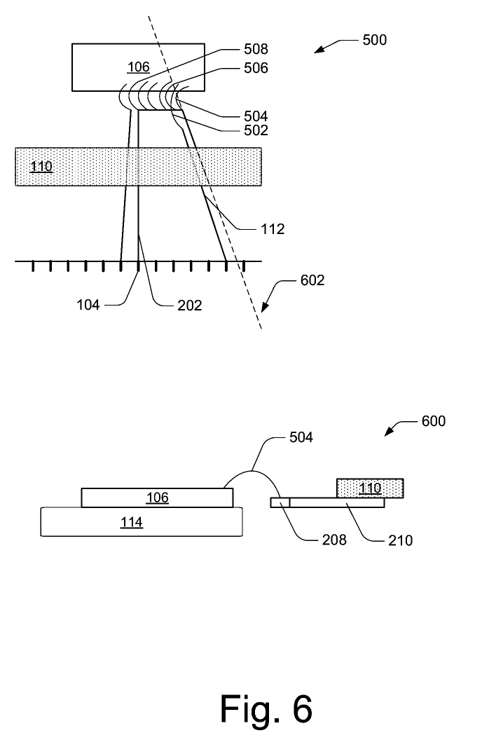

View 600 of FIG. 6 is a cross-section indicated by dashed line 602 of view 500 (view 500 repeated on FIG. 6 for the reader's convenience). A portion of lead-frame substructure 114 is shown for context. Die-connect section 208 of multi-connect lead 202 is shown and is electrically connected to integrated circuit die 106 via wire 504. Lead supporter 110 is in contact with support section 210 but not with die-connect section 208. Lead supporter 110 provides mechanical support to support section 210, which in turn provides mechanical support to die-connect section 208.

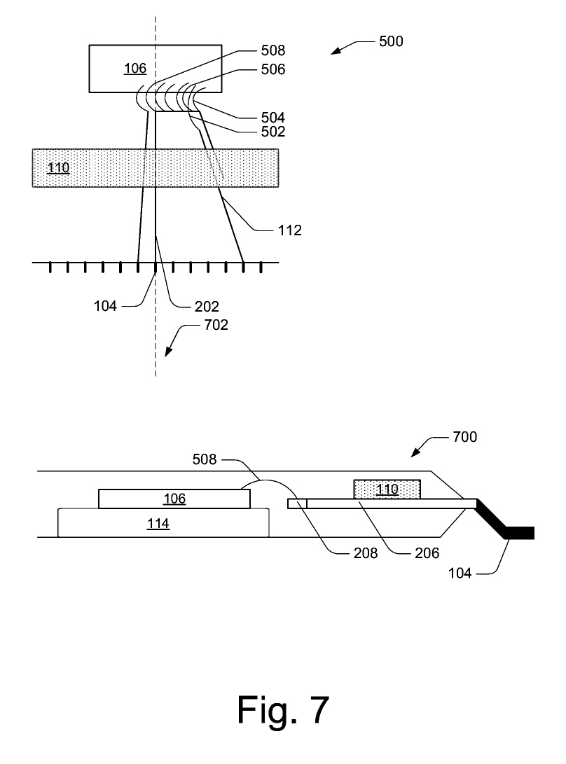

View 700 of FIG. 7 is a cross-section indicated by dashed line 702 of view 500 (again shown for convenience). A portion of lead-frame substructure 114 is shown for context. Die-connect section 208 of multi-connect lead 202 is shown and is electrically connected to integrated circuit die 106 via wire 508. Pin-connect section 206 is in contact with external pin 104 as well as die-connect section 208. Lead supporter 110 is in contact with pin-connect section 206 but not with die-connect section 208.

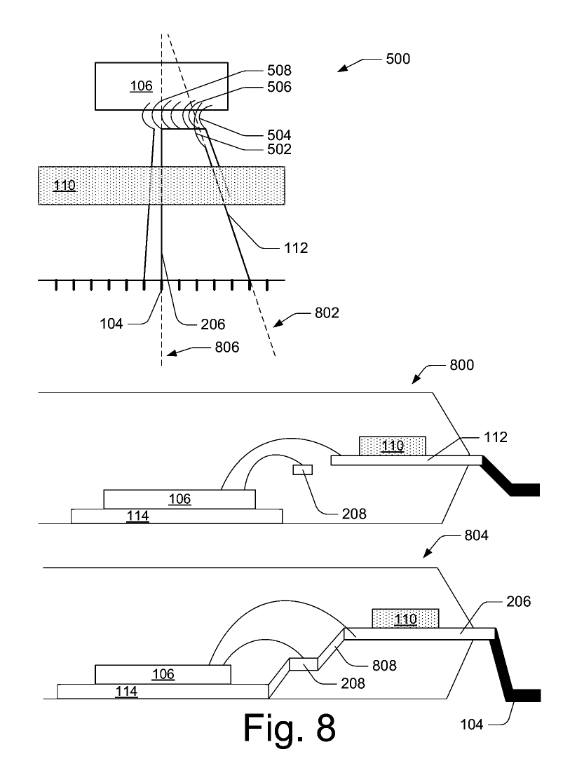

While the leads in FIGS. 5-7 have been shown on a single level of elevation, multiple levels are contemplated, some of which are illustrated in FIG. 8. View 800 is a cross-section indicated by dashed line 802 of view 500 (illustrated in FIG. 8 for convenience). A portion of lead-frame substructure 114 is shown for context. Die-connect section 208 of multi-connect lead 202 is shown at a lower level than single-connect lead 112. View 804 is a cross-section indicated by dashed line 806 of view 500. A portion of lead-frame substructure 114 is shown for context. Die-connect section 208 is shown at a lower level than the majority of pin-connect section 206, both of multi-connect lead 202. Pin-connect section 206 includes a level-bridging sub-section 808 that connects die-connect section 208 with a remaining portion of pin-connect section 206.

Method for Conserving External Pins and/or Space

This disclosure describes techniques for conserving external pins and/or space occupied by leads on a chip package. These techniques may include the method described below, as well as other techniques described elsewhere herein.

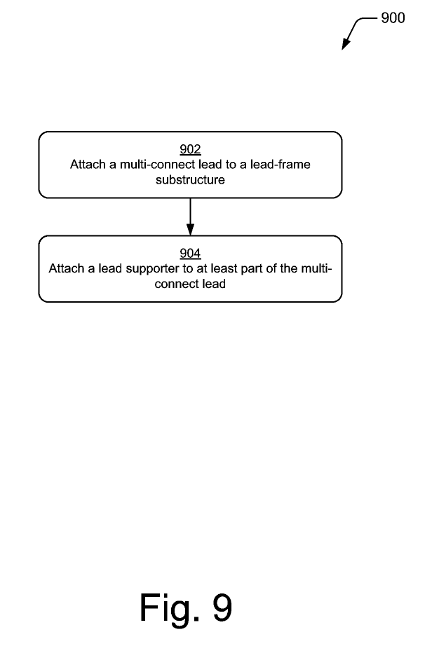

FIG. 9 illustrates a method 900 for conserving external pins and/or space occupied by leads on a chip package. At 902, a multi-connect lead, such as those described above, is attached to a lead-frame substructure. Attaching the multi-connect lead may include constructing the multi-connect lead through applying and shaping a continuous conductive material over the lead-frame substrate 114 or by applying and connecting multiple pieces of a conductive material. Examples include application by photo lithography, chemical vapor deposition, sputtering, and physical-wire application. Attaching the multi-connect lead may instead include attaching a pre-constructed multi-connect lead. In either case, a pin-connect section of the multi-connect lead is attached to an external pin.

At 904, a lead supporter is attached to at least part of the multi-connect lead, such as to the pin-connect section and a support section of the multi-connect lead. The lead supporter provides mechanical support to the multi-connect lead and is described above.

By way of example, consider application of method 900 to the chip package illustrated in FIG. 1. At 902, a multi-connect lead 108 is attached to lead-frame substructure 114 and to a single external pin 104. One or more other multi-connect leads 108 and/or single-connect leads 112 are attached to lead-frame substructure 114, each lead connected to one of external pins 104. At 904, lead supporter 110 is attached to lead frame 116. Lead supporter 110 is in contact with single and multi-connect leads, such as 108 and 112. Lead supporter 110 is connected to the multi-connect lead's pin-connect section and support section.

To create a completed chip package, integrated circuit die 106 is attached to lead-frame substructure 114, wires are attached to electrically connect leads 108 and 112, a structural material is applied that covers integrated circuit die 106, lead supporter 110, and lead frame 116 (except that at least part of each external pin 104 remains exposed). The structural material can be applied as a liquid or other flexible form of non-conductive plastic and later hardened, though other materials or manners of application can be used. This completed chip package can be mounted on a printed circuit board for use, with external pins 104 electrically connecting contacts on the printed circuit board to an integrated circuit within integrated circuit die 106.

Although the subject matter has been described in language specific to structural features and/or methodological techniques and/or acts, it is to be understood that the subject matter defined in the appended claims is not necessarily limited to the specific features, techniques, or acts described above, including orders in which they are performed.

What is claimed is:

1. An apparatus comprising:
an external pin configured to establish an electrical connection to an external apparatus;
a multi-connect lead comprising
a pin-connect section directly connected to the external pin,
a die-connect section directly connected to the pin-connect section, the die-connect section configured to allow multiple electrical connections to an integrated circuit die, and
a support section directly connected to the die-connect section, the support section (i) providing support to the die-connect section and (ii) having an end electrically and physically terminating the multi-connect lead; and
a lead supporter in contact with the pin-connect section and the support section but not in contact with the die-connect section, the lead supporter providing mechanical support to the support section and the pin-connect section.

2. The apparatus as recited in claim 1, further comprising the integrated circuit die.

3. The apparatus as recited in claim 1, wherein:
the multi-connect lead comprises a continuous material; and
the pin-connect, die-connect, and support sections are functional divisions of the continuous material.

4. The apparatus as recited in claim 1, wherein:
the support section is a first support section; and
the apparatus further comprises a second support section (i) directly connected to the die-connect section and (ii) in contact with the lead supporter.

5. The apparatus as recited in claim 1, wherein the die-connect section is directly connected to the pin-connect section at less than or about a ninety-degree angle.

6. The apparatus as recited in claim 1, wherein the die-connect section is directly connected to the pin-connect section at greater than or about a ninety-degree angle.

7. The apparatus as recited in claim 1, wherein the die-connect section is directly connected to the support section at greater than or about a ninety-degree angle.

8. The apparatus as recited in claim 1, wherein the die-connect section is directly connected to the support section at less than or about a ninety-degree angle.

9. The apparatus as recited in claim 1, wherein the lead supporter comprises a non-conductive plastic.

10. The apparatus as recited in claim 1, further comprising a single-connect lead.

11. The apparatus as recited in claim 10, wherein the die-connect section is at a first elevation and the single-connect lead is at a second elevation, the first elevation not being equal to the second elevation.

12. A chip package comprising:
an integrated circuit die;
an external pin mounted to the chip package, the external pin configured to establish an electrical connection to an external apparatus;
a multi-connect lead mounted to the chip package, the multi-connect lead comprising
a pin-connect section directly connected to the external pin, and
a die-connect section directly connected to the pin-connect section, the die-connect section (i) configured to allow multiple electrical connections to the integrated circuit die and (ii) having an end electrically and physically terminating the multi-connect lead; and
a lead supporter in contact with the pin-connect section but not in contact with the die-connect section, the lead supporter providing mechanical support to the pin-connect section.

13. The chip package as recited in claim 12, further comprising the multiple electrical connections to the integrated circuit die from the die-connect section.

14. The chip package as recited in claim 12, wherein:
the multi-connect lead comprises a continuous material; and
the pin-connect and die-connect sections are functional divisions of the continuous material.

15. A method comprising:
attaching a multi-connect lead to a lead-frame substructure, the multi-connect lead comprising
a pin-connect section directly connected to an external pin, the external pin residing on an outside edge of the lead-frame substructure,
a die-connect section directly connected to the pin-connect section, the die-connect section configured to allow multiple electrical connections to an integrated circuit die, and
a support section directly connected to the die-connect section, the support section (i) providing support to the die-connect section and (ii) having an end electrically and physically terminating the multi-connect lead; and
attaching a lead supporter to the pin-connect section and the support section but not to the die-connect section.

16. The method as recited in claim 15, further comprising:
attaching the integrated circuit die to the lead-frame substructure; and
attaching wires to the integrated circuit die and the die-connect section to create the multiple electrical connections.

17. The method as recited in claim 16, further comprising:
applying a structural material over at least a portion of each of the multi-connect lead, the integrated circuit die, the lead supporter, the lead-frame substructure, and the external pin, the applying leaving exposed at least part of the external pin; and
hardening the structural material, thereby creating a complete chip package.

18. The method as recited in claim 17, further comprising mounting the complete chip package onto a printed circuit board, the mounting including electrically connecting the external pin to a contact on the printed circuit board.

19. The method as recited in claim 15, further comprising attaching, to the lead-frame substructure, a single-connect lead configured to allow a single electrical connection to the integrated circuit die and at a first elevation, the first elevation different than a second elevation of the die-connect section of the multi-connect lead.

20. The method as recited in claim 15, wherein the support section is a first support section and the multi-connect lead includes a second support section directly connected to the die-connect section and in contact with the lead supporter.
